(19) United States
(12) Patent Application Publication
(10) Pub. No.: US 2020/0312849 A1
(43) Pub. Date: Oct. 1, 2020

(54) GATE RECESS UNIFORMITY IN VERTICAL FIELD EFFECT TRANSISTOR

(71) Applicant: International Business Machines Corporation, Armonk, NY (US)

(72) Inventor: Kangguo Cheng, Schenectady, NY (US)

(21) Appl. No.: 16/362,903

(22) Filed: Mar. 25, 2019

(51) Int. Cl. H01L 27/105; H01L 29/06; H01L 27/092; H01L 29/417; H01L 29/66; H01L 29/78; H01L 21/8238

(52) U.S. Cl. CPC H01L 27/105; H01L 29/0653; H01L 27/0924; H01L 29/41791; H01L 21/823878; H01L 29/66795; H01L 29/7827; H01L 21/823821; H01L 29/66666

(57) ABSTRACT

An approach to provide an array of vertical field effect transistors that includes a plurality of vertical field effect transistors and at least one isolation structure. The approach includes a first dielectric material covering a gate material of the plurality of vertical field effect transistors and filling a first isolation structure of the at least one isolation structures, where the gate material is a uniform height on each fin of the array of vertical field effect transistors and the first isolation structure is located with a same distance to an adjacent fin as a distance between each fin in each vertical field effect transistor in the array of vertical field effect transistors. The approach includes a second dielectric material surrounding the first isolation structure, wherein the second isolation structure does not extend under the adjacent fin.

### BACKGROUND OF THE INVENTION

The present invention relates generally to the field of semiconductor device formation and particularly to the formation of vertical field effect transistors.

Semiconductor device fabrication is a series of processes used to create integrated circuits present in electronic devices such as computers. The emergence of vertical field effect transistor devices as integrated circuit devices provides an opportunity for continued reductions in device scaling for complimentary-metal oxide semiconductor (CMOS) devices. Each vertical field effect transistor (VFET) includes a fin with a channel, a source/drain (S/D) below the channel, a S/D above the channel, and a gate on fin sidewalls. As device scaling continues to shrink, in accordance with Moore's Law, VETs provide opportunity for increased dense packing and decreased device to device pitch as VFETs, unlike horizontally oriented devices, decouples gate length from device pitch.

### SUMMARY

Embodiments of the present invention disclose an array of vertical field effect transistors comprising a plurality of vertical field effect transistors and at least one isolation structure where a first dielectric material covers a gate material of the plurality of vertical field effect transistors and fills a first isolation structure of the at least one isolation structures. Embodiments of the present invention disclose the gate material is a uniform height on each fin of the array of vertical field effect transistors. Embodiments of the present invention disclose the first isolation structure is located with a same distance to an adjacent fin as a distance between each fin in each vertical field effect transistor in the array of vertical field effect transistors. Embodiment of the present invention disclose a second dielectric material surrounds the first isolation structure, wherein the second isolation structure does not extend under the adjacent fin.

Embodiments of the present invention provide a method of forming an array of vertical field effect transistors with a uniform gate length. The method includes removing a portion of a bottom source/drain layer and a portion of the semiconductor substrate adjacent to a dummy fin of in a plurality of fins in an array on the bottom source/drain layer forming a first trench in a semiconductor structure. The method includes depositing a conformal layer of a first dielectric material on top of the bottom source/drain layer, the hardmask, on sidewalls of the plurality of fins, and filling the first trench. The method includes removing the first dielectric material from exposed surfaces of the bottom source/drain layer, the hardmask, and sidewalls of the plurality of fins and depositing a bottom spacer on exposed surfaces of the bottom source/drain layer. The method includes depositing, on exposed surfaces of the plurality of in fins and bottom spacer, a gate dielectric material and a gate material on the gate dielectric material. Additionally, the method includes depositing a sacrificial material over the gate material and recessing the sacrificial material to a uniform height on each fin of the plurality of fins. The method includes etching exposed gate material and the gate dielectric material under the exposed gate material and etching the dummy fin and a portion of the bottom source/drain layer and a portion of the semiconductor substrate under the dummy fin forming a second trench. The method further includes removing remaining sacrificial material and conformally depositing a second dielectric material over the gate material, the exposed surfaces of the plurality of fins, and filling the second trench.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 depicts a cross-sectional view of a semiconductor structure including a substrate with a S/D layer under a plurality of fins that include a hardmask on top of each of the plurality of fins, in accordance with an embodiment of the present invention.

FIG. 2 depicts a cross-sectional view of the semiconductor structure after fabrication steps depositing a patterned etch mask and a removing a portion of the S/D layer and a portion of the substrate not covered by a patterned etch mask, in accordance with an embodiment of the present invention.

FIG. 3 depicts a cross-sectional view of the semiconductor structure after fabrication steps removing a patterned etch mask, in accordance with an embodiment of the present invention.

FIG. 4 depicts a cross-sectional view of the semiconductor structure after fabrication steps depositing a conformal dielectric layer on the semiconductor structure, in accordance with an embodiment of the present invention.

FIG. 5 depicts a cross-sectional view of the semiconductor structure after fabrication steps removing the conformal dielectric layer from the fins and the top surface of the S/D layer, in accordance with an embodiment of the present invention.

FIG. 6 depicts a cross-sectional view of the semiconductor structure after fabrication steps depositing a bottom spacer on the top surface of the S/D layer and a top surface of the shallow isolation trench, in accordance with an embodiment of the present invention.

FIG. 7 depicts a cross-sectional view of a semiconductor structure after fabrication steps depositing a layer of gate material over a layer of gate dielectric on the bottom spacer and the plurality of fins, in accordance with an embodiment of the present invention.

FIG. 8 depicts a cross-sectional view of the semiconductor structure after fabrication steps depositing a layer of sacrificial material over the gate material, in accordance with an embodiment of the present invention.

FIG. 9 depicts a cross-sectional view of the semiconductor structure after fabrication steps removing a portion of the sacrificial material layer uniformly between each of the plurality of fins to a desired height of the optical planarization material layer, in accordance with an embodiment of the present invention.

FIG. 10 depicts a cross-sectional view of the semiconductor structure after fabrication steps removing exposed portions of the gate material and the dielectric layer under the exposed gate material on a top portion of each of the plurality of fins, in accordance with an embodiment of the present invention.

FIG. 11 depicts a cross-sectional view of the semiconductor structure after fabrication steps depositing and patterning an etch mask over the semiconductor structure and removing an exposed fin, a portion of the S/D layer under the exposed fin, and a portion of the substrate under the exposed fin, in accordance with an embodiment of the present invention.

FIG. 12 depicts a cross-sectional view of the semiconductor structure after fabrication steps removing the patterned mask and the remaining sacrificial material layer, in accordance with an embodiment of the present invention.

FIG. 13 depicts a cross-sectional view of the semiconductor structure after fabrication steps depositing a dielectric layer on the exposed portions of the gate material, the gate dielectric layer, the plurality of fins remaining, and in the recess of the removed fin, in accordance with an embodiment of the present invention.

FIG. 14 depicts a cross-sectional view of the semiconductor structure after fabrication steps depositing and planarizing a layer of interlevel dielectric removing a top portion of the fin including the hardmask, in accordance with an embodiment of the present invention.

FIG. 15 depicts a cross-sectional view of a semiconductor structure after fabrication steps forming a top S/D by a selective etch of a portion of the interlevel dielectric layer, and S/D deposition on an exposed top surface of each fin, in accordance with an embodiment of the present invention.

FIG. 16 depicts a cross-sectional view of the semiconductor structure after fabrication steps forming contacts by deposition a layer of another dielectric material over the semiconductor structure and various contacts are formed, in accordance with an embodiment of the present invention.

FIG. 17 depicts a cross-sectional view of the semiconductor structure in a second embodiment after fabrication steps removing the portion of the sacrificial material layer uniformly between each of the plurality of fins to deposit and pattern an etch mask over the semiconductor structure, in accordance with an embodiment of the present invention.

FIG. 18 depicts a cross-sectional view of the semiconductor structure in a second embodiment of the present invention after fabrication steps removing an exposed fin, a portion of gate dielectric on the exposed fin, a portion of the S/D layer under the exposed fin, and a portion of the substrate under the exposed fin, in accordance with an embodiment of the present invention.

FIG. 19 depicts a cross-sectional view of a semiconductor structure in a second embodiment of the present invention after fabrication steps removing the exposed portions of the gate dielectric and exposed portions gate material under removed gate dielectric, in accordance with an embodiment of the present invention.

FIG. 20 depicts a cross-sectional view of the semiconductor structure in a second embodiment of the present invention after fabrication steps removing the patterned etch mask and the sacrificial material layer, in accordance with an embodiment of the present invention.

FIG. 21 depicts a cross-sectional view of the semiconductor structure in a second embodiment of the present invention after fabrication steps depositing a layer of the dielectric material on the exposed surfaces of the gate material, the fin, and in the recess created by the removed exposed fin, in accordance with an embodiment of the present invention.

FIG. 22 depicts a cross-sectional view of the semiconductor structure in a second embodiment of the present invention after fabrication steps depositing a layer of interlevel dielectric and form contacts on top of each of the plurality of fins, in accordance with an embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. Some of the process steps, depicted, can be combined as an integrated process step. In addition, descriptions of well-known functions and constructions may be omitted for clarity and conciseness.

The terms and words used in the following description and claims are not limited to the bibliographical meanings, but, are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Detailed embodiments of the claimed structures and methods are disclosed herein. The method steps described below do not form a complete process flow for manufacturing integrated circuits on semiconductor chips. The present embodiments can be practiced in conjunction with the integrated circuit fabrication techniques for semiconductor chips and devices currently used in the art, and only so much of the commonly practiced process steps are included as are necessary for an understanding of the described embodiments. The figures represent cross-section portions of a semiconductor chip or a substrate, such as a semiconductor wafer during fabrication and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment,” etc., indicate that the embodiment described may include a particular feature, structure or characteristic, but every embodiment may not necessarily include the particular feature, structure or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

Reference will now be made in detail to the embodiments of the present invention, examples of which are illustrated in the accompanying drawings, wherein like reference numerals refer to like elements throughout.

Embodiments of the present invention recognize vertical field effect transistors (VFETs) typically use a timed etch process to determine gate length. Embodiments of the present invention recognize that the gate length is typically defined by depositing a gate workfunction metal, filling gaps between deposited workfunction metal with a sacrificial material, recessing sacrificial material between fins, and then laterally etching exposed workfunction metal to create a gate of required gate length. Embodiments of the present invention recognize that variations in the sacrificial material recess commonly occur due to an effect of multiple fins or multiple VFETs on sacrificial material recess depth, particularly on sacrificial material recess height on fins in VFETs present in outer regions of an array or group of multiple VFETs. Embodiments of the present invention recognize that variations in the sacrificial material recesses causes non-uniform height of the sacrificial material between fins forming VFETs. Embodiments of the present invention recognize that variations in sacrificial material recess depth results in gate length variations. Embodiment of the present invention recognize variations in gate height commonly occurs on fins of VFETs located in an outer edge of an array fins in a plurality of VFETs in response to sacrificial material regions associated with an outer edge of an array or group of fins experiencing a higher degree of sacrificial material etching due to loading effect during sacrificial material removal (e.g., interior fins have less sacrificial material removed and exterior sides of outer or exterior fins in the group have more sacrificial material removed). Embodiments of the present invention recognize non-uniformity of sacrificial material etch and non-uniform sacrificial material recess height results in non-uniform gate length, which causes undesirable variation in VFET electrical characteristics and variations in VFET electrical performance.

Embodiments of the present invention provide a method to improve uniformity of gate length in VFETs. In particular, embodiments of the present invention provide a method to improve uniformity of sacrificial material height on fins of VFETs in an array of VFETs, resulting in a more uniform or uniform gate length on the fins of the array of VFETs. Embodiments of the present invention improve gate length uniformity in an array of VFETs and provides improved electrical performance of VFETs of an array of VFETs by providing VFETs with similar electrical characteristics and performance.

Embodiments of the present invention provide a method and structure for fabricating VFETs with a more uniform or uniform sacrificial material layer height within a recess created between gates formed with a workfunction metal and provides uniform isolation. Embodiments of the present invention remove identified fins or dummy fins, which may be called isolation fins, after gate patterning.

Embodiments of the present invention recognize that one or more isolation structures, such as shallow trench isolation (STI), can be created in one or more portions of a semiconductor substrate and a bottom source/drain around a base of a fin that is a dummy fin prior to dummy fin removal. Embodiments of the present invention recognize that one or more dummy fins and portions of source/drain and a substrate under the dummy fin(s) are removed from specific areas of an array of fins (e.g., at outer edges of an array of fins or between identified dummy fins in the array to provide isolation between different types of VFET transistors). Embodiments of the present invention provide a dielectric material deposited conformally over a VFET structure, filling a dummy fin opening and recess formed by removal of a portion of source/drain and substrate under the removed dummy fin to form isolation structures. Embodiments of the present invention recognize that filling an opening or trench by pinching off or filling the created dummy fin recess can form an isolation feature between VFETs. Embodiments of the present invention recognize that the dielectric material additionally provides protection for the gate during subsequent processing steps.

Embodiments of the present invention recognize that in arrays of fins forming VFETs with three of more fins using one or more dummy fins in one or more locations provides a method of creating a uniform gate length for a group of an array of VFETs and provides required isolation for VFETs and between various types of VFET, such as nFET and pFET vertical field effect transistors. Embodiments of the present invention provide a method of forming one or more single fin VFET devices. Embodiments of the present invention provide a method of forming one or more VFET devices where each VFET device is composed of multiple fins connected together. Embodiments of the present invention provide a method of forming one or more VFET devices where each VFET device is composed of multiple fins connected together and one or more single fin VFET devices in one or more arrays of VFET devices.

Embodiments of the present invention provide a method of forming VFETs on the outer edges of an array of VFETs with a uniform gate length by removing dummy fins on outer edges of the array and provides required isolation structures. Embodiments of the present invention provide a method and structure for fabricating various types of VFET transistor devices, such as nFETs and pFETs, various types of connections between VFET transistor devices, and various isolation structures. In particular, embodiments of the present invention provide a method of fabricating an inverter using an array of fins, a dummy fin, and two shallow trench isolation structures for forming various nFET transistors as VFETs and pFET transistors as VFETs with a contact connecting more than one nFET transistor, a contact connecting more than one pFET transistor, and a contact providing a common gate connection for the respective one or more nFET and pFET transistors. Embodiments of the present invention provide a method of fabricating VFETs, not limited to the creation of inverters, but that can be used in the fabrication of any VFET device, any array or multiple arrays of VFET devices, other suitable semiconductor device or arrays of suitable semiconductor devices.

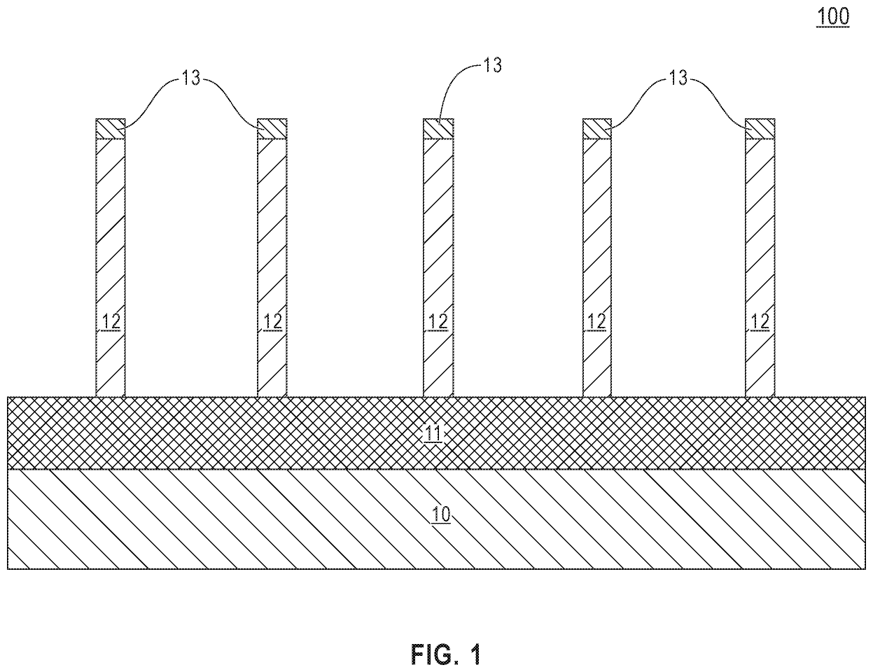

FIG. 1 depicts a cross-sectional view of semiconductor structure 100 including substrate 10 with source/drain (S/D) layer 11 under a plurality of fins 12 with hardmask (HM) 13 on top of each of the plurality of fins 12, in accordance with an embodiment of the present invention. Semiconductor structure 100 is depicted with the plurality of fins 12 over S/D layer 11 but, is not limited to the number of fins 12 depicted. For example, semiconductor structure 100 includes two or more fins 12 with HM 13 where at least one of the plurality of fins 12 is a dummy fin (e.g., a fin removed at a later step of VFET device fabrication). Semiconductor structure 100 may be fabricated with conventional fabrication processes.

Substrate 10 may be composed of any semiconductor material. In various embodiments, substrate 10 is a wafer or a portion of a wafer. In various embodiments, semiconductor substrate 10 is composed of one of any group III-V semiconductor material, group II-VI semiconductor material, or group IV semiconductor material. In some embodiments, substrate 10 is composed of one of a silicon material, a germanium material, a silicon germanium material, a indium gallium arsenide material, a silicon carbide material, a indium phosphide material, a indium antimonide, or other similar compound semiconductor material. In other examples, substrate 10 may be composed of materials including, for example, SiGeC, SiC, GaAs, InAs, other III-V compound semiconductor materials, other single element semiconductor material, ZnTe, CdTe, ZnCdTe, or other II-VI compound semiconductor materials or alloys of GaAlAs, InGaAs, InAlAs, InAlAsSb, InAlAsP, and InGaAsP. In some embodiments, substrate 10 is one of doped, undoped, or contains doped regions, undoped regions, or defect rich regions. In an embodiment, substrate 10 is one of a layered semiconductor substrate, such as a semiconductor-on-insulator substrate (SOI) or silicon-on-replacement insulator (SRI). In an embodiment, substrate 10 is silicon substrate.

S/D layer 11 is a layer of material capable of creating a bottom source or a bottom drain for semiconductor device, such as a VFET device. In various embodiments, S/D layer 11 is formed by epitaxy. In some embodiments, S/D layer 11 is formed by other semiconductor processes. S/D layer 11 is depicted as a single material however, S/D layer 11 is not limited to a single material. While S/d layer 11 can be composed of a single material as depicted in FIG. 1, portions of S/D layer 11 can be composed of different materials for different transistors in some embodiments. For example, a portion of S/D layer 11 can be a phosphorous doped silicon (Si:P) layer for a nFET transistor device and another portion of S/D layer 11 can be a boron doped silicon germanium (SiGe) layer for a pFET transistor device. In an example of semiconductor structure 100 where S/D layer 11 in semiconductor structure 100 is composed of more than one material, a first portion of S/D layer 11 can be formed using a mask material over a portion of substrate 10 allowing epitaxial growth of a pFET S/D material, such as boron doped silicon germanium, for the first portion of S/D layer 11 and after mask material removal and a second mask exposed another portion of substrate 10 allowing epitaxial growth of a nFET S/D material, such as a phosphorous doped silicon on a second portion of S/D layer 11. Alternatively, in another example, one or more materials for S/D layer 11 are doped in one or more portions of substrate 10 forming S/D layer 11 by, for example, ion implantation, gas phase doping, plasma doping, plasma immersion ion implantation, cluster doping, infusion doping, liquid phase doping, solid phase doping, and/or any suitable combination of those techniques. In some embodiments, dopants are activated by thermal annealing such as laser annealing, flash annealing, rapid thermal annealing (RTA) or any suitable combination of those techniques. In other embodiments, the annealing process is omitted.

The plurality of fins 12 include HM 13 on top of fins 12 and reside on S/D layer 11. In various embodiments, processes compatible with VFET device fabrication are utilized in forming the plurality of fins 12. HM 13 can be composed of any known hardmask material that protects fins 12 during various VFET processing steps. For example, HM 13 can be SiN deposited one of known hardmask deposition processes, such as plasma-enhanced (PE) chemical vapor deposition (CVD) and atomic layer deposition (ALD).

In various embodiments, at least one of the plurality of fins 12 is a dummy fin, which may also be known as an isolation fin, that is removed in a later process step. In an embodiment, the plurality of fins includes three or more fins. The plurality of fins 12 can be composed of any known fin material for fin formation in semiconductor devices. For example, fins 12 can be composed of silicon, germanium, SiGe, or any of the semiconductor materials used in substrate 10. In some embodiments, fins 12 are silicon fins or silicon germanium fins. Fins 12 can be formed with any thickness or width and on any spacing. For example, fins 12 may have a width ranging from 5 nanometers to 50 nanometers but, are not limited with this width. For example, fins 12 can have a width of 10 nanometers or less. Fins 12 may be spaced from 15 nanometers to 200 nanometers apart, for example, although fin spacing is not limited to this spacing in various semiconductor structures 100.

In various embodiments, the plurality of fins 12 are uniformly distributed in at least one array of fins over the surface of semiconductor structure 100. In an embodiment, an array of fins is three of more fins. For example, fins 12 in an array have a uniform or same spacing of 20 nanometers of less. In some embodiments, when the plurality of fins 12 is an array of fins, at least the outermost or last fins 12 of the array (e.g., the fins on the outside edges of the plurality of fins 12) are dummy fins. In some embodiments, more than one array of fins for the plurality of fins 12 exists on semiconductor structure 100. For example, two arrays or grouping of fins can be present in the plurality of fins 12 on semiconductor structure 100 where a spacing of 20 nanometers exists in a first array of fins 12 and another spacing of 28 nanometers exists in a second array of fins 12. Similarly, a first array or grouping of fins 12 can have one or more of a different width, shape, or size than a second array of fins 12 in the plurality of fins 12 on semiconductor structure 100. Additionally, as discussed above with reference to S/D layer 11, an array of fins, a portion of an array of fins, or more than one array of fins can be associated with more than one material for S/D layer 11 (e.g., a portion of an array of fins or a number of fins 12 are on S/D layer 11 composed of a pFET material or boron doped SiGe). Stated differently, in some embodiments, different fins are fabricated above different S/D materials.

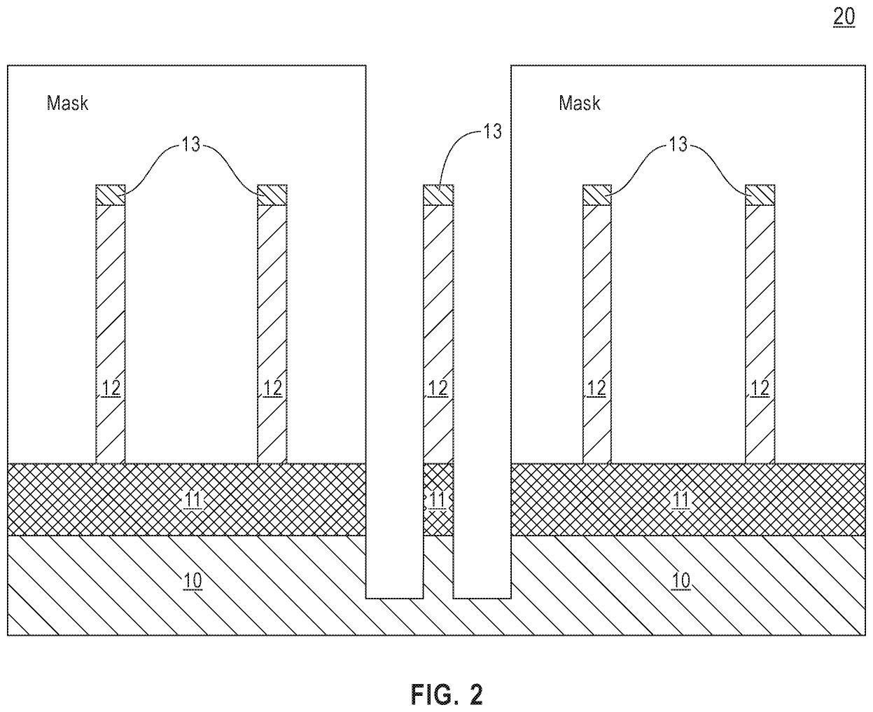

FIG. 2 depicts a cross-sectional view of semiconductor structure 20 after fabrication steps depositing patterned etch mask deposition and removing a portion of S/D layer 11 and a portion of substrate 10 not covered by the patterned etch mask, in accordance with an embodiment of the present invention. As depicted, FIG. 2 includes the elements of semiconductor structure 20 and a patterned etch mask after partially removing a portion of S/D layer 11 not covered by the etch mask and a top portion of substrate 10 under the removed portion of S/D layer 11. HM 13 protects any of the plurality of fins 12 left exposed by the etch mask during S/D layer 11 and substrate 10 removal. For example, a dummy fin of the plurality of fins 12 is protected by HM 13 during one or more etch processes. Around the bottom or base of a dummy fin of the plurality of fins 12, a first directional etch can be used to remove the exposed portions of S/D layer 11 and substrate 10. For example, anisotropic etch using a reactive ion etch (RIE) is used to remove one or more portions of S/D layer 11 and one or more portions of substrate 10 exposed by the etching process of S/D layer 11 where each of portion of the one or more portions of S/D layer 11 combined with a portion of the one or more portions of substrate 10 removed provide an area suitable for isolation trench formation in later processing steps.

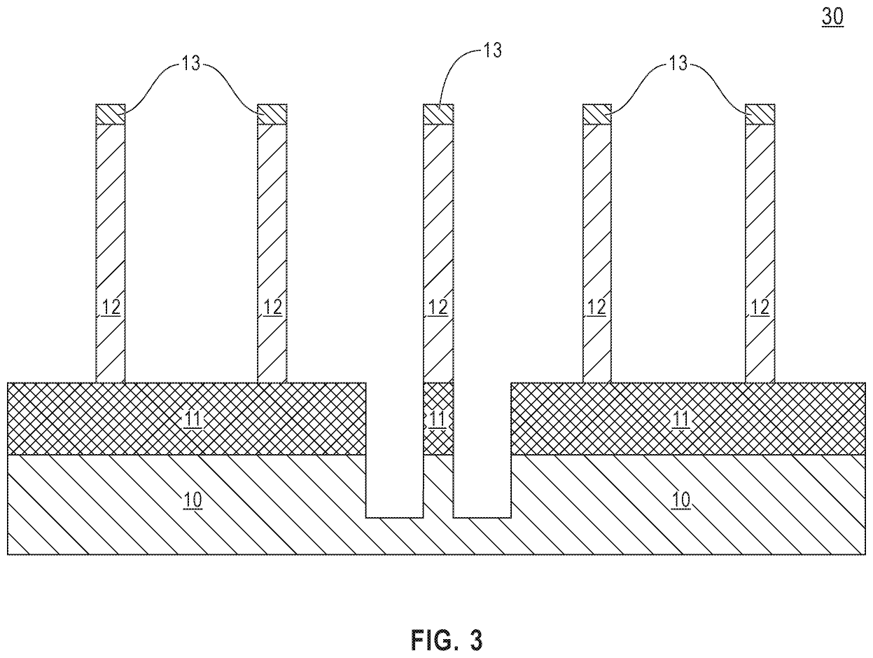

FIG. 3 depicts a cross-sectional view of semiconductor structure 30 after fabrication steps removing the patterned etch mask, in accordance with an embodiment of the present invention. As depicted FIG. 3 includes the elements of semiconductor structure 100 after removal of the patterned etch mask, a portion of S/D layer 11, and a portion of substrate 10 around or adjacent to a base of the dummy fin. Although FIG. 3 illustrates a portion of S/D layer 11 and a portion of substrate 10 surrounding a dummy fin, in various embodiments, more than one portion of S/D layer 11 and substrate 10 are removed adjacent to the bottom of a dummy fin of fins 12. For example, in another embodiment, not depicted in FIG. 3, six portions of S/D layer 11 and six portions of substrate 10 are removed adjacent to three dummy fins of fins 12 (e.g., two portions of S/D layer 11 and substrate 10 are removed adjacent to the bottom of each of the three dummy fins).

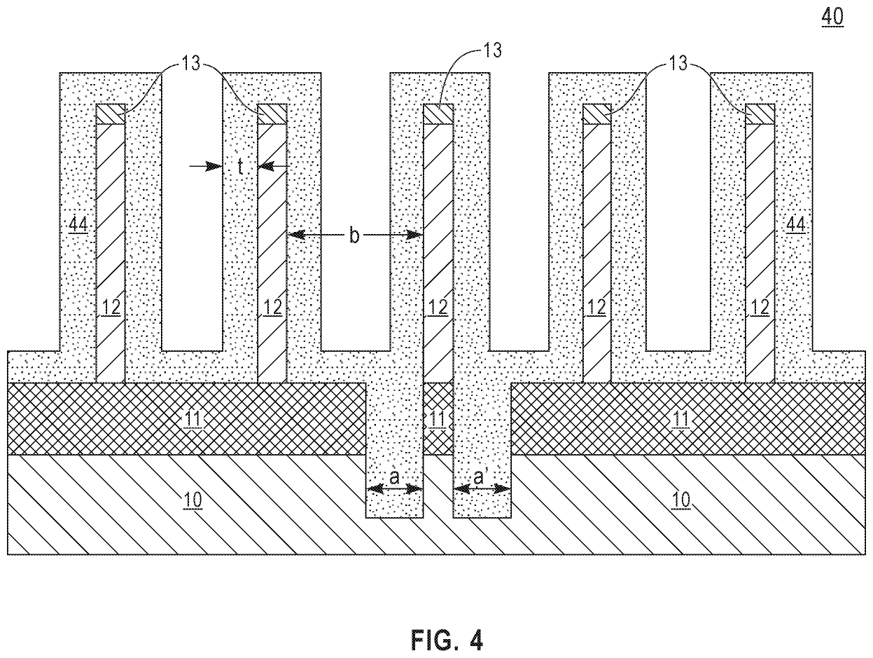

FIG. 4 depicts a cross-sectional view of semiconductor structure 40 after fabrication steps depositing conformal dielectric layer 44 on the semiconductor structure 40, in accordance with an embodiment of the present invention. As depicted FIG. 4 includes the remaining portions of substrate 10, S/D layer 11, and fins 12 with HM 13 covered with conformal dielectric layer 44. Conformal dielectric layer 44 may be deposited uniformly over the various elements on the top surface of semiconductor structure 40 and fill recesses in substrate 10 and S/D layer 11 created by removal of the portions of substrate 10 and S/D layer 11 as depicted in FIG. 2 and FIG. 3.

In various embodiments, the thickness of conformal dielectric layer 44 is greater than one half the width of isolation trench and is less than one half of the spacing between adjacent fins 12. Stated differently, the conformal dielectric layer 44 should be deposited such that it completely fills the recesses without pinching off the spacing between adjunct fins. For example, the thickness of conformal dielectric layer 44 is “t” as depicted in FIG. 4, which is greater than ½ the width of isolation trench, depicted as “a” in FIG. 4, and t, the thickness of dielectric conformal layer 44 is less than ½ the spacing between adjacent fins 12 depicted as “b” in FIG. 4 (e.g., ½ a <t<½ b). The deposition of conformal dielectric layer 44 completely fills the recess created by the removal of the portions of S/D layer 11 and the portions of substrate 10 to form isolation trenches for VFET device formation. Conformal dielectric layer 44, deposited by an appropriate deposition process to create an isolation trench, is composed of any suitable dielectric material. For example, conformal dielectric layer 44 may be an oxide, such as SiO₂ or SiN. The conformal dielectric layer 44 can be deposited, for example, by CVD or ALD. The conformal dielectric completely fills the recess by pinching off. In some embodiments, dielectric layer 44 is deposited in a trench formed around a bottom of a dummy fin of the plurality of fins 12. In this example, dielectric layer 44 can form a single isolation structure, such as a shallow trench isolation (STI). Dielectric layer 44 filling a trench in a portion of S/D layer 11 and substrate 10 created adjacent to a base or bottom of a dummy fin forms one of a ring, an annular structure, an oval structure, a rectangular structure, or other shape determined, based in part, on a shape of a dummy fin of fins 12. In various embodiments, dielectric layer 44 forms two isolation trenches or two isolation structures adjacent to the base or bottom of a dummy fin of fins 12. In some embodiments, a single isolation structure is formed in a portion of S/D layer 11 and substrate 10 around outside bottom edges of a dummy fin of fins 12. In one embodiment, more than one isolation structure is formed adjacent to a base or bottom of a dummy fin of fins 12.

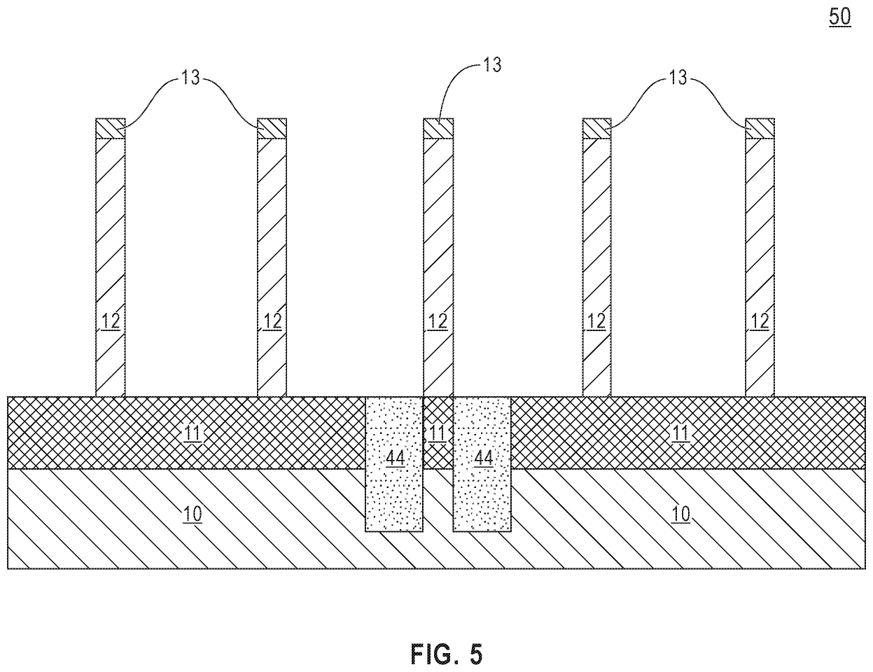

FIG. 5 depicts a cross-sectional view of semiconductor structure 50 after fabrication steps removing portions conformal dielectric layer 44 from surfaces of fins 12 and HM 13 and from the top surface of S/D layer 11, in accordance with an embodiment of the present invention. As depicted, FIG. 5 includes the remaining portions of substrate 10, S/D layer 11, and conformal dielectric layer 44 along with the plurality of fins 12 and HM 13. After an isotropic etch of conformal dielectric layer 44 from the sidewall of fins 12 and exposed top surfaces of S/D layer 11, the remaining portions of conformal dielectric layer 44 reside in the recess or recesses formed by the previous removal of the portions of substrate 10 and the portions of S/D layer 11 adjacent or surrounding one of fins 12. The remaining portions of conformal dielectric layer 44 become shallow isolation trenches (STI) and, hereinafter will be called STI 44. As previously discussed, STI 44 can be one annular isolation structure or two separate isolation structures adjacent to the base of a dummy fin. As previously discussed, the portions of substrate 10 and the portions of S/D layer 11 may be removed from area adjacent to or surrounding a bottom of more than one dummy fin and similarly, more than two trenches 44 can be formed. For example, in another embodiment not depicted, four trenches or four STI 44 may be formed around two fins 12 (e.g., two dummy fins of the plurality of fins 12).

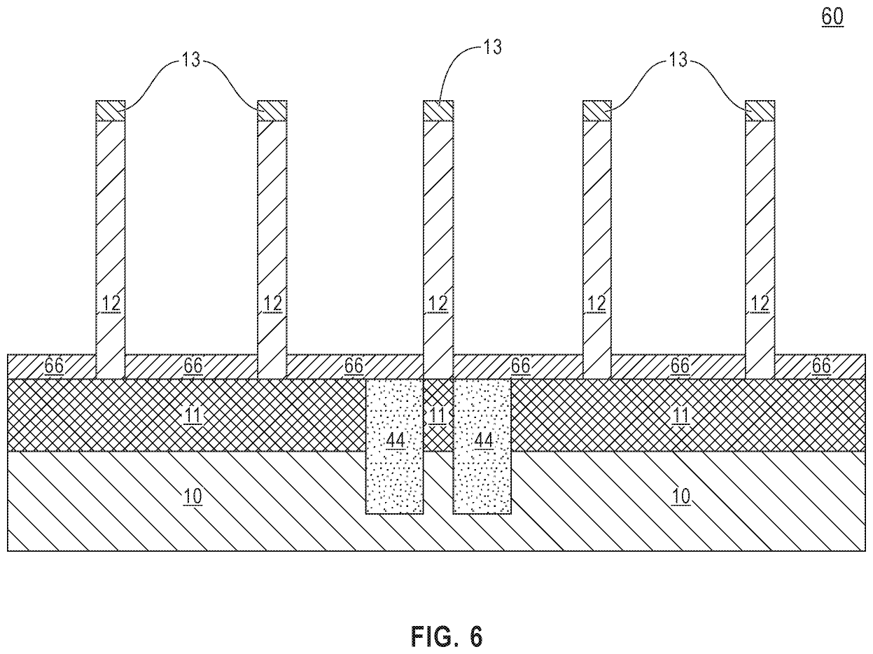

FIG. 6 depicts a cross-sectional view of semiconductor structure 60 after fabrication steps depositing bottom spacer 66 on the top surface of S/D layer 11 and top surfaces of STI 44, in accordance with an embodiment of the present invention. In various embodiments, bottom spacer 66 deposits on horizontal surfaces of semiconductor structure 60. Bottom spacer 66 is a dielectric material and can be any material used for spacer formation in field effect transistors. For example, bottom spacer 66 can be SiN or an oxide, such as SiO₂ created by conventional processes for spacer formation (e.g., CVD, high-density plasma deposition, and the like).

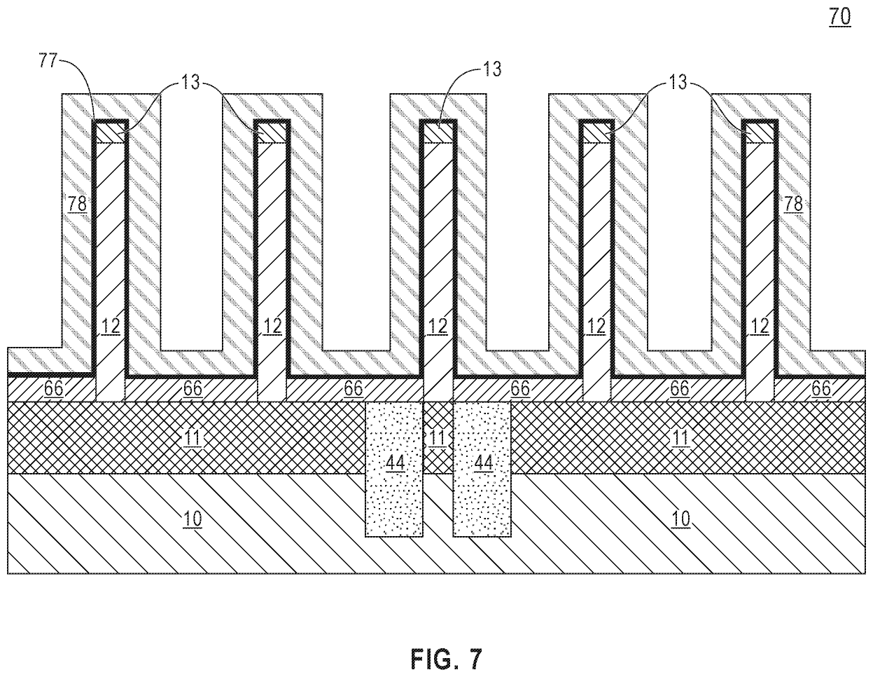

FIG. 7 depicts a cross-sectional view of semiconductor structure 70 after fabrication steps depositing a layer of gate material 78 over a layer of gate dielectric 77 on the bottom spacer 66 and the plurality of fins 12, in accordance with an embodiment of the present invention. In various embodiments, gate dielectric 77 can be any suitable dielectric material deposited over the surface of semiconductor structure 70. For example, gate dielectric 77 can comprise any suitable dielectric material, including but not limited to silicon oxide, silicon nitride, silicon oxynitride, high-k materials, or any combination of these materials. Examples of high-k materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k dielectric materials may further include dopants such as lanthanum, aluminum, magnesium. Gate dielectric 77 can be formed by any suitable process or any suitable combination of multiple processes, including but not limited to, thermal oxidation, chemical oxidation, thermal nitridation, plasma oxidation, plasma nitridation, atomic layer deposition (ALD), chemical vapor deposition (CVD), etc. In some embodiments, the gate dielectric has a thickness ranging from lnm to 5nm, although less thickness and greater thickness are also conceived.

Gate material 78 can include any suitable conducting material, including but not limited to, doped polycrystalline or amorphous silicon, germanium, silicon germanium, a metal (e.g., tungsten (W), titanium (Ti), tantalum (Ta), ruthenium (Ru), hafnium (Hf), zirconium (Zr), cobalt (Co), nickel (Ni), copper (Cu), aluminum (Al), platinum (Pt), tin (Sn), silver (Ag), gold (Au), a conducting metallic compound material (e.g., tantalum nitride (TaN), titanium nitride (TiN), tantalum carbide (TaC), titanium carbide (TiC), titanium aluminum carbide (TiA1C), tungsten silicide (WSi), tungsten nitride (WN), ruthenium oxide (RuO2), cobalt silicide (CoSi), nickel silicide (NiSi)), transition metal aluminides (e.g. Ti3Al, ZrA1), TaC, TaMgC, carbon nanotube, conductive carbon, graphene, or any suitable combination of these materials. The conductive material may further comprise dopants that are incorporated during or after deposition. In some embodiments, the gate may further comprise a workfunction setting layer between the gate dielectric and gate conductor. The workfunction setting layer can be a workfunction metal (WFM). WFM can be any suitable material, including but not limited a nitride, including but not limited to titanium nitride (TiN), titanium aluminum nitride (TiAlN), hafnium nitride (HfN), hafnium silicon nitride (HfSiN), tantalum nitride (TaN), tantalum silicon nitride (TaSiN), tungsten nitride (WN), molybdenum nitride (MoN), niobium nitride (NbN); a carbide, including but not limited to titanium carbide (TiC) titanium aluminum carbide (TiAlC), tantalum carbide (TaC), hafnium carbide (HfC), and combinations thereof In some embodiments, a conductive material or a combination of multiple conductive materials can serve as both gate conductor and WFM. The gate conductor and WFM can be formed by any suitable process or any suitable combination of multiple processes, including but not limited to, atomic layer deposition (ALD), chemical vapor deposition (CVD), physical vapor deposition (PVD), sputtering, plating, evaporation, ion beam deposition, electron beam deposition, laser assisted deposition, chemical solution deposition, etc.

While depicted in FIG. 7 as the same gate material 78 and gate dielectric 77, in some embodiments, different materials can be deposited on various fins of the plurality of fins 12. In various embodiments, different transistor devices (e.g., nFETs and pFET) may require different gate workfunction metals for different portions of gate material 78 in an array of fins or in a portion of an array of fins according to the type of transistor device desired for the VFET devices. In these cases, the portion of gate material 78 associated a first transistor device (e.g., nFET) and a first fin of fins 12 associated with the transistor device can be different from a portion of gate material 78 associated with a second transistor device (e.g., pFET) and a second fin of fins 12 associated with the second transistor device. For example, one of fins 12 associated with a nFET transistor for a VFET device may have TiAlC or other suitable nFET workfunction metal for gate material 78 over and adjacent to the fin while one of adjacent fins 12 associated with a pFET for a VFET device may have TiN or other suitable pFET workfunction metal for gate material 78 and adjacent to the adjacent fin 12. The use of different gate material 78 associated with different transistor device may be accomplished by depositing a first gate workfunction metal associated with a first transistor device over the top surface of semiconductor structure 70, applying an etch mask patterned to remove gate material 78 associated with the first transistor in area associated with a second transistor device (e.g., over first fins 12 and adjacent horizontal surfaces adjacent to fins 12 associated with the second transistor device), removing the areas of gate material 78 associated with the second transistor device, and depositing a second gate workfunction metal associated with the second transistor device in the areas associated with the second transistor device (e.g., fins 12 and adjacent horizontal surfaces adjacent to second fins 12). Gate material 78 can be deposited by any known gate deposition process (e.g., ALD, CVD, and the like). In various embodiments, gate material 78 is deposited with a uniform thickness over gate dielectric 77.

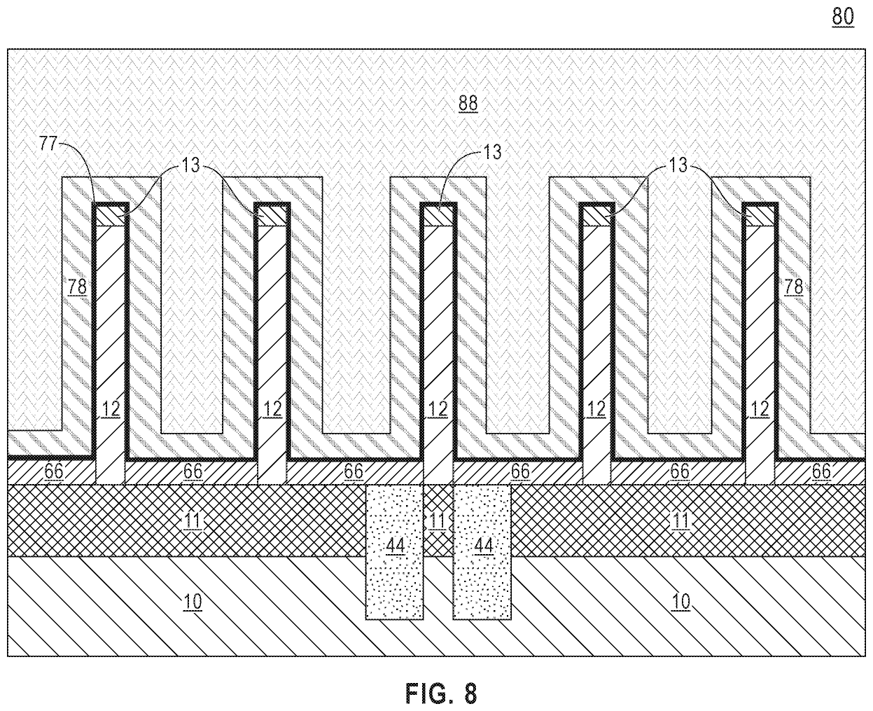

FIG. 8 depicts a cross-sectional view of semiconductor structure 80 after fabrication steps depositing a layer of sacrificial material 88 over gate material 78, in accordance with an embodiment of the present invention. A layer of sacrificial material 88 is deposited over the top surface of semiconductor structure 80. Sacrificial material 88, for example, is a material deposited and subsequently removed before VFET device completion. In various embodiments, sacrificial material 88 is an optical planarization layer (OPL). For example, sacrificial material 88 can be composed of polyacrylate resin, epoxy resin, phenol resin, polyamide resin, polyimide resin, unsaturated polyester resin, polyphenylenether resin, polyphenylene sulfide resin, benzocyclobutene (BCB) or a combination thereof. Sacrificial material 88 can be formed using chemical vapor deposition (CVD), spinning from solution, spraying from solution, and evaporation. Additionally, in some embodiments, sacrificial material 88 is an amorphous carbon or other suitable sacrificial material. Sacrificial material 88 fills gaps between the plurality of fins 12 and provides an essentially uniform surface when fins 12 are uniformly distributed in an array.

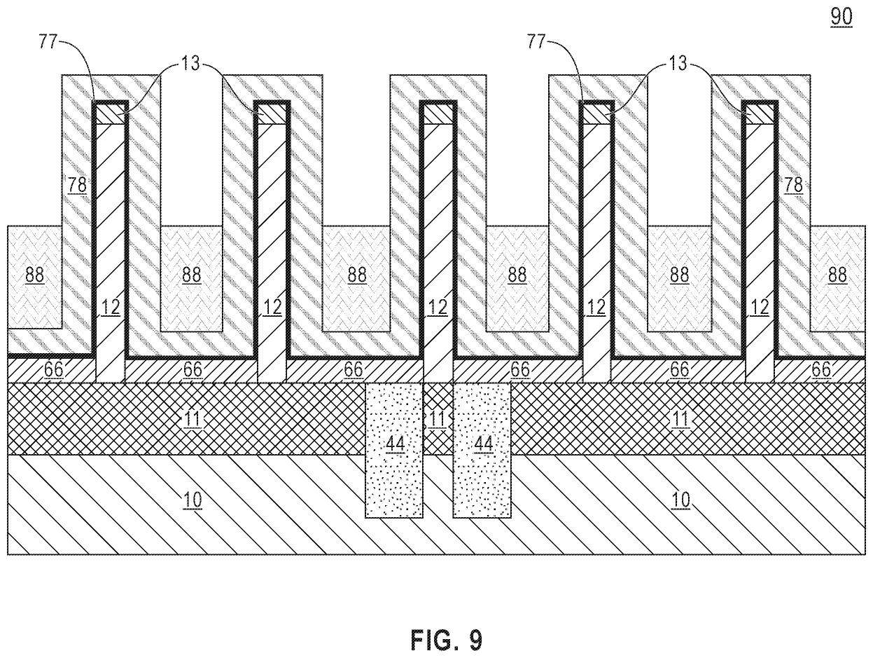

FIG. 9 depicts a cross-sectional view of the semiconductor structure 90 after fabrication steps removing a portion of sacrificial material 88 uniformly between each of the plurality of fins 12 to a desired height of sacrificial material 88 layer, in accordance with an embodiment of the present invention. An etch process may be used to remove sacrificial material 88 on semiconductor structure 90. In various embodiments, sacrificial material 88 is removed between the plurality of fins 12 to a uniform height on gate material 78 on each side of fins 12. Sacrificial material 88 is removed from the top portions of gate material 78 on the top portions of the plurality of fins 12 and is uniformly removed between the plurality of fins 12. In various embodiments, sacrificial material 88 is removed layer by layer to a desired height on gate material 78 on each side of the fins in the plurality of fins 12. The removal of sacrificial material 88 can occur using a precision etch process providing a more uniform sacrificial material 88 depth between the plurality of fins 12. For example, a plasma etch may be used to remove sacrificial material 88 to a uniform height between the plurality of fins 12 (e.g., removing sacrificial material 88 to the same height on the sides of the fins) forms a recess between each of the fins in the array of fins). Systematically removing sacrificial material 88 layer by layer, for example, using controlled etch processes provides a uniform height of sacrificial material 88 remaining between the fins in the plurality of fins 12 that are in an array of fins with a uniform spacing. In one embodiment, sacrificial material 88 is recessed by a plasma that contains 30 sccm to 100 sccm hydrogen bromide (HBr), 30 sccm to 100 sccm CO2, 20 sccm to 80 sccm O2, 100 sccm to 300 sccm helium (He), a pressure ranging from 10 mTorr to 50 mTorr, a top radio frequency (RF) power that ranges from 300 W to 800 W, and a low RF power that ranges from 80 W to 250 W. In one example, sacrificial material 88 is etched by a plasma that contains 50 sccm hydrogen bromide (HBr), 70 sccm CO2, 50 sccm O₂ and 200 sccm He, with a pressure of 25 mTorr, and top RF power of 500 W, and bottom RF power of 150 W. In another example, a reactive ion etch (RIE) process may be used.

When the height or a depth of the remaining sacrificial material 88 between fins 12 is not uniform, a non-uniform gate length can occur in the final VFET device because when an etch removing gate material 78 and gate dielectric 77 occurs in subsequent steps, the gate length associated with the remaining gate material 78 on the sides of fins 12 with a non-uniform height of remaining sacrificial material 88 will also be non-uniform as the height of the remaining gate material 78 after subsequent etch processes will also be non-uniform. In other words, the height of the remaining sacrificial material 88 on gate material 78 on the sides of fins 12 determines a height of gate material 78 on the sides of fins 12 after subsequent etch processes. A non-uniform height of sacrificial material 88 on the sides of fins 12 in the array of fins results in a non-uniform gate length of various resulting VFET devices after completion of VFET processing.

In various embodiments, a uniform spacing between fins 12 and a uniform size and shape of fins 12 provides simpler etch processing to remove or recess sacrificial material 88 to a uniform height. Providing a uniform spacing between the plurality of fins 12 and the uniform size of each of the fins in the plurality of fins 12 also aides in ensuring a uniform sacrificial material 88 thickness across an area of the semiconductor substrate populated with the plurality of fins 12 after deposition of sacrificial material 88. When areas of the plurality of fins 12 have a different spacing and/or a different size fins, additional etch masks and adjustments to etching process, such as etch time, additional number of etches, or adjustments to other etch process parameters in order to provide uniformity of sacrificial material 88 height on gate material 78 on the sides of fins 12 (e.g., between fins) when a portion or portions of the plurality of fins 12 are in an array of fins of either a different size of fins 12 or a different spacing of fins 12 in different arrays of fins. Variations in etch processes or etch parameters may be needed to obtain a uniform sacrificial material 88 height on the sides of fins 12 in various areas or portions of an array or different arrays of fins 12.

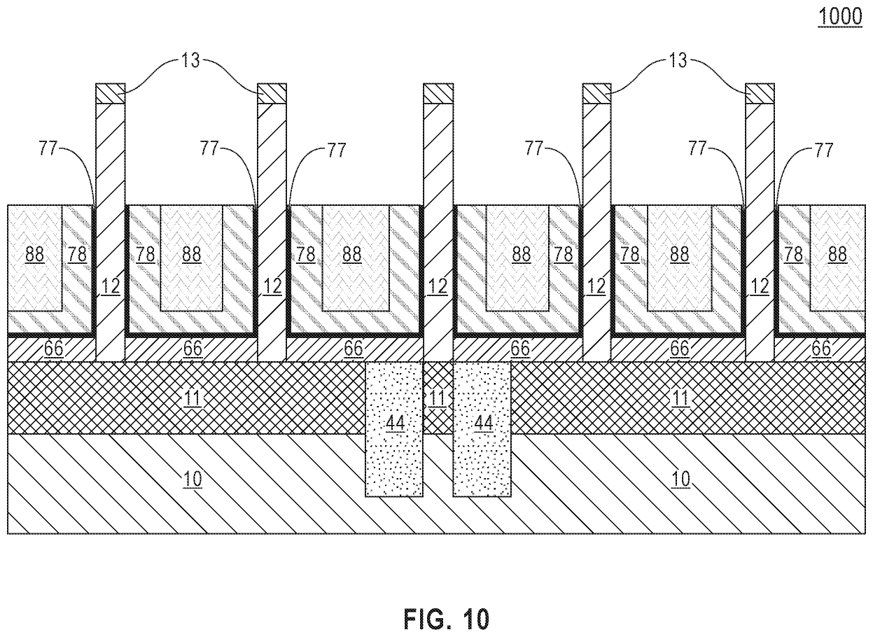

FIG. 10 depicts a cross-sectional view of semiconductor structure 1000 after fabrication steps removing exposed portions of gate material 78 and gate dielectric 77 under exposed portions of gate material 78 on a top portion of each of the plurality of fins 12, in accordance with an embodiment of the present invention. In various embodiments, removing exposed portions of gate material 78 and gate dielectric 77 under removed gate material 78 provides a uniform gate height due to uniform height of remaining sacrificial material 88 in recesses between the plurality of fins 12 (i.e., as discussed with reference to FIG. 9). For example, removal of gate material 78 and gate dielectric 77 can occur using one or more etch processes, such as a dry etch process (e.g., RIE) or wet etching (e.g., chemical etch) and may utilize various etch masks and/or photolithography processes/patterning. Removing exposed portions of gate material 78 and gate dielectric 77 when uniform sacrificial material 88 levels are provided in recesses between the plurality of fins 12 provides a uniform gate length. In various embodiments, providing uniform sacrificial material 88 height in recesses between adjacent fins 12 reduces variations in gate height in fins 12 after removal of gate material 78 and gate dielectric 77 from exposed top surfaces reduces gate length variations in fins adjacent to other fins in the plurality of fins 12.

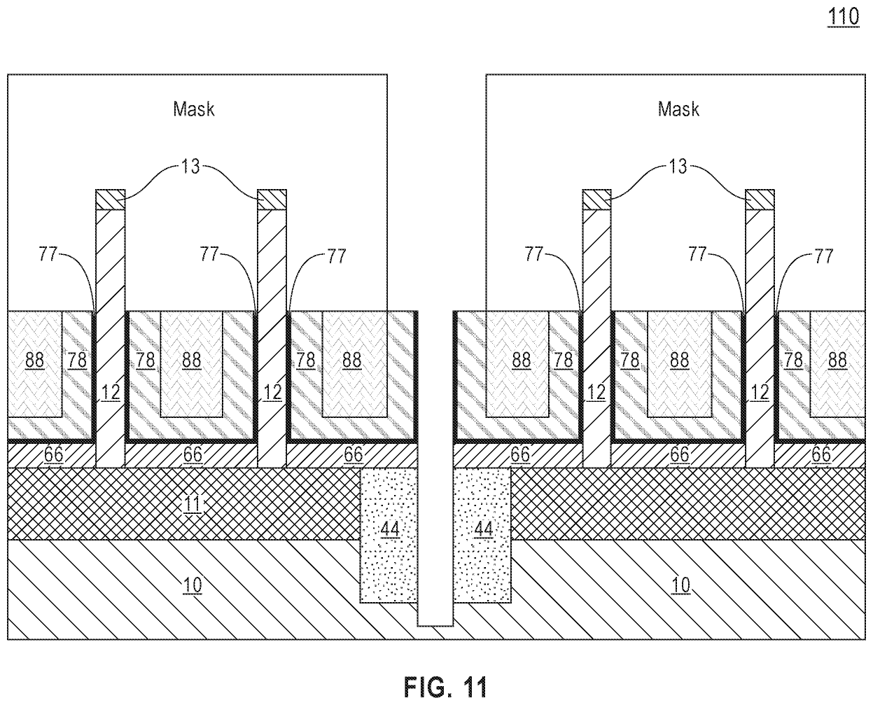

FIG. 11 depicts a cross-sectional view of semiconductor structure 110 after fabrication steps depositing and patterning an etch mask over the top of semiconductor structure 110 and removing an exposed fin 12, a portion of S/D layer 11 under the exposed fin 12, and a portion of substrate 10 under the exposed fin 12, in accordance with an embodiment of the present invention. As depicted in FIG. 11, the exposed fin 12 of the plurality of fins 12, which may also be referred to as a dummy fin or an isolation fin, is removed. One or more etch processes can be used to remove one or more of dummy fins of the plurality of fins 12 and HM 13 on the dummy fins exposed by the etch mask. In various embodiments, the one or more removed fins 12 (e.g., dummy fins) of the plurality of fins 12 and the removed portions of S/D layer 11 and substrate 10 create another trench or another trench for isolation.

In an embodiment, a removed fin (e.g., dummy fin) or a line of removed fins is removed in an area between two arrays of fins of the plurality of fins 12. For example, the removed fin or dummy fin is removed between fins formed with a different gate material 78 (e.g., for different types of transistor types or between nFET and pFET transistors), between different sized fins or arrays with different spacing. In some embodiments, one or more removed fins (e.g., dummy fins) reside on an outer edge of an array of fins 12. For example, providing dummy fins to be removed along an outer edge or each outer edge of an array of fins 12 provides a uniform height of sacrificial material 88 on the sides of fins 12 in the array and, upon completion of resulting VFET devices, provides improved uniformity in gate length of VFET devices formed from the array of fins remaining of the plurality of fins 12. The one or more etch processes remove a portion of S/D layer 11 under the exposed fin of the plurality of fins 12 and a portion of substrate 10 under the removed S/D layer 11 and the removed fin. In some embodiments, sacrificial material 88 is removed before applying the etch mask.

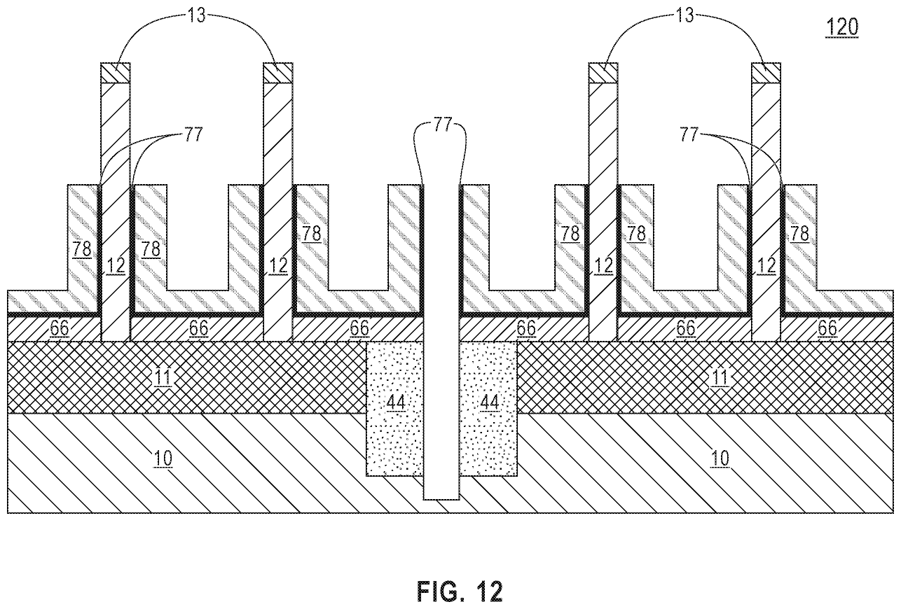

FIG. 12 depicts a cross-sectional view of semiconductor structure 120 after fabrication steps removing patterned etch mask and remaining sacrificial material 88 layer, in accordance with an embodiment of the present invention. Patterned etch mask can be stripped from the top surface of semiconductor structure 120. In various embodiments, one or more etch processes remove sacrificial material 88 remaining in the recesses between the plurality of fins 12.

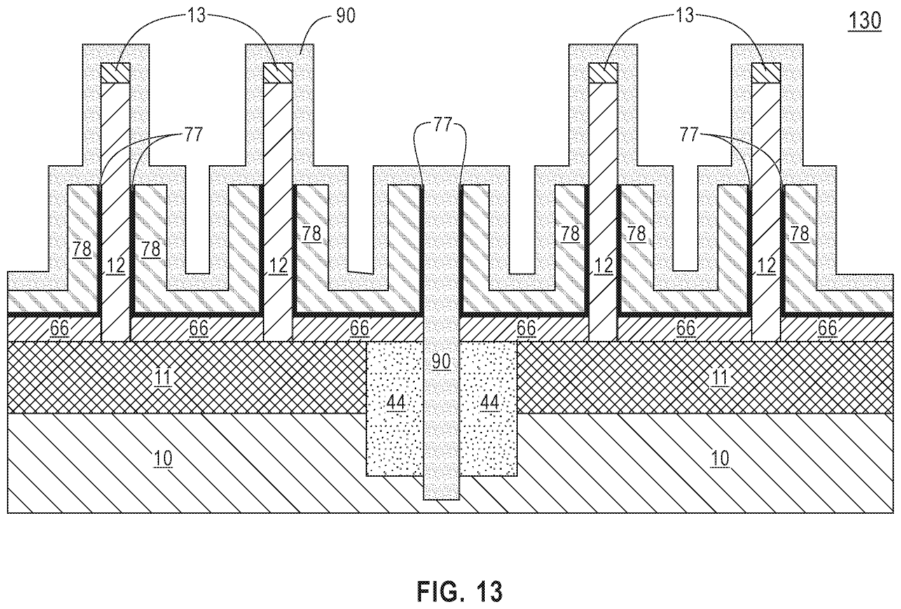

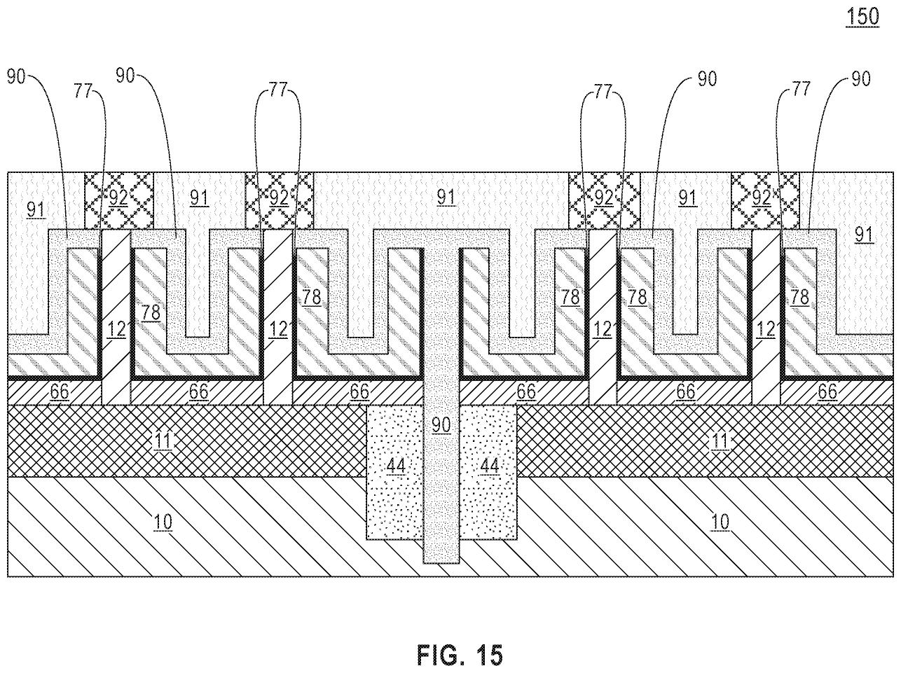

FIG. 13 depicts a cross-sectional view of semiconductor structure 130 after fabrication steps depositing deposit dielectric material 90 on the exposed portions of gate material 78, gate dielectric 77, the plurality of fins 12 remaining, and in the recess of the removed fin, in accordance with an embodiment of the present invention. As depicted in FIG. 13, a dielectric material 90 is deposited over the exposed surfaces of semiconductor structure 130 filling the recess or recesses created by the removal of one or more of dummy fins of the plurality of fins 12. In various embodiments, dielectric material 90 serves as a spacer between the gate material 78 and a top source/drain formed in a later step (e.g., formed in FIG. 15). Dielectric material 90 can be deposited with a suitable deposition process and may use the deposition processes, such as ALD, CVD, or other similar processes, for example. Deposition processes for dielectric material 90 can the same processes or different processes used in depositing bottom spacer 66. Dielectric material 90 can be any suitable dielectric material for a VFET device. For example, dielectric material 90 can be SiN, SiON, SiBCN, SiOCN, SiOC, an oxide, or other dielectric material used in FET devices. In one embodiment, dielectric material 90 is deposited with a thickness greater than one half the width of the removed dummy fin. For example, when a width of one of fins 12 is 10 nanometers wide, a thickness of as deposited dielectric material 90 (e.g., SiN) can be 6 nanometers. In various embodiments, dielectric material 90 protects gate material 78 forming the gate for VFET device and fills the opening or recess created by the removal of one or more dummy fins of the plurality of fins 12. For example, dielectric material 90 fills or pinches off recesses formed when dummy fins, the portions of S/D layer 11 under the dummy fins, and the portions of substrate 10 under dummy fins are removed. In various embodiments, dielectric material 90 deposited in the recess created by the removal of a dummy fin and portions of S/D layer 11 and substrate 10 under the removed dummy fin create an isolation structure.

In some embodiments, a location of the isolation structure created by filling the trench created by the removal of the dummy fin and associated portions of S/D layer 11 and substrate 10 is on a same spacing as a spacing of fins in the array of fins or an array of VFET devices, upon completion. In an embodiment, the isolation structure is a same distance to each adjacent fin as a spacing of the array in which the adjacent fins is a part of In an embodiment, a spacing of the isolation structure to two adjacent fins varies if the two adjacent fins are in different arrays of fins with a different spacing. For example, if the isolation structure is adjacent to a fin in an array with a spacing of 20 nanometers on the left, the isolation structure can be 20 nanometers from the adjacent fin on the left and can be 14 nanometers from an adjacent fin to the right in an array with a 14 nanometer spacing between fins.

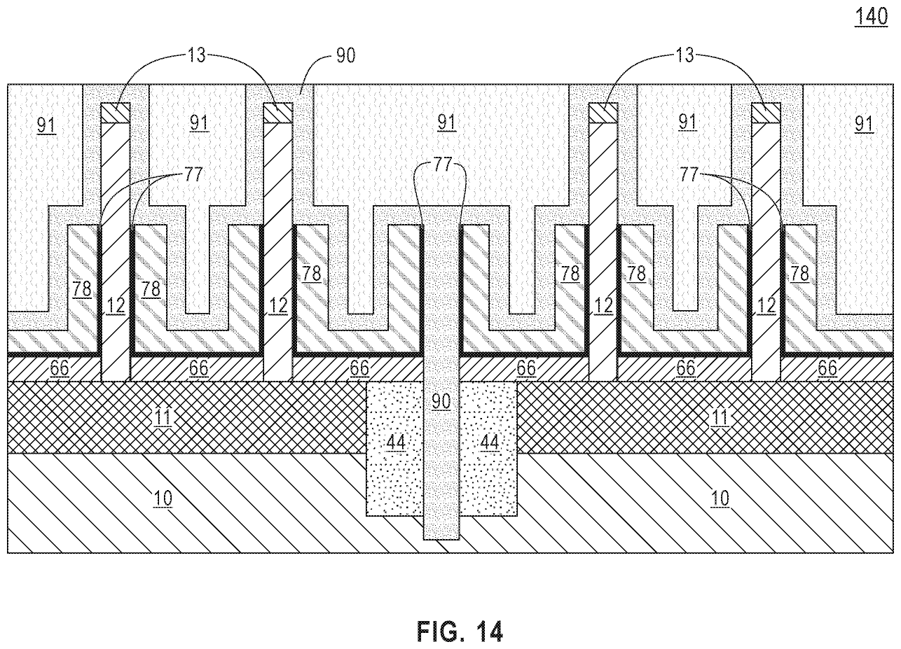

FIG. 14 depicts a cross-sectional view of semiconductor structure 140 after fabrication steps depositing a layer of interlevel dielectric (ILD) 91, in accordance with an embodiment of the present invention. ILD 91 is deposited over semiconductor structure 140 using conventional ILD deposition methods, such as oxide deposited by CVD or spin-on method. ILD 91 can be any commonly used ILD material in VFET formation.

FIG. 15 depicts a cross-sectional view of semiconductor structure 150 after planarizing and fabricating top S/D 92 by a selective etch of a portion of ILD 91 and top S/D 92 deposition on an exposed top surface of each of fins 12, in accordance with an embodiment of the present invention. Planarization of ILD 91 occurs with conventional planarization processes, such as chemical-mechanical polishing (CMP). In various embodiments, during planarization, HM 13 and top portions of the plurality of fins 12 remaining are removed.

In various embodiments, top S/D 92 is formed after a selective etch of ILD 91. For example, using a patterned etch mask, a portion of ILD 91 over each of the remaining fins 12 and over a portion of dielectric material 90 over a portion of gate material 78 can be removed. Top S/D 92 is deposited with suitable S/D deposition methods for a VFET device. For example, in-situ doped epitaxy can be used to create top S/D 92. Other suitable methods to create top S/D 92 includes, but are not limited to, ion implantation, gas phase doping, plasma doping, plasma immersion ion implantation, cluster doping, infusion doping, liquid phase doping, solid phase doping, and/or any suitable combination of those techniques. In some embodiments, dopants are activated by thermal annealing such as laser annealing, flash annealing, rapid thermal annealing (RTA) or any suitable combination of those techniques.

While depicted as a single material in FIG. 15, top S/D 92 is composed of more than one material in various embodiments. For example, in some cases, for different VFET transistor devices, a different material for top S/D 92 is deposited in association with different fins 12 and/or different VFET transistor devices (e.g., as previously discussed with respect to S/D layer 11 in FIG. 1). For example, if one or more of the plurality of fins 12 is associated with a VFET transistor device that is an nFET then, top S/D 92 can be phosphorous doped silicon. Similarly, if one or more of the plurality of fins 12 is associated with a VFET transistor device that is a pFET then, top S/D 92 can be a boron doped silicon germanium. This can be done, for example, using masks and processes as previous discussed in reference to FIG. 1.

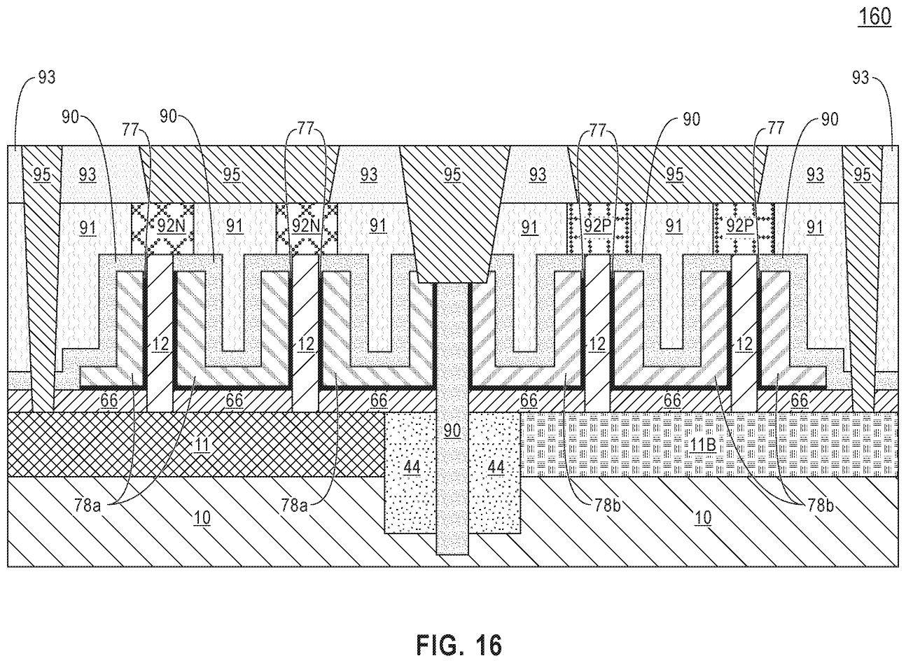

FIG. 16 depicts a cross-sectional view of semiconductor structure 160 after fabrication steps to form contacts 95 by deposition a layer of another dielectric material 93 over the semiconductor structure 160 that is selectively patterned for deposition of contacts 95, in accordance with an embodiment of the present invention. In various embodiments, dielectric material 93 is any suitable VFET dielectric material, including but not limited to, silicon oxide, silicon oxycarbide (SiOC), carbon doped silicon oxide (SiO:C), fluorine doped silicon oxide (SiO:F), boron carbon nitride (BCN), hydrogen silsesquioxane polymer (HSQ), methyl silsesquioxane polymer (MSQ), methyl doped silica (SiO:(CH3)), organosilicate glass (SiCOH), porous SiCOH, and combinations thereof. In some embodiments, dielectric material 93 is an ultra-low-k dielectric. For example, dielectric material 93 can be SiOCH or other similar ultra-low-k dielectric material. In some embodiment, dielectric material 93 is a second interlevel dielectric or a second ILD surrounding contacts 95 and covering ILD 91 and a portion of top S/D 92N and 92P. In some embodiments, one or more of dielectric material 93, dielectric material 90, ILD 91, and bottom spacer 66 are composed of a same material.

In various embodiments, a plurality of contacts 95 are formed. For example, as depicted in FIG. 16, five contacts 95 are depicted (e.g., two bottom source/drain contacts, a contact connecting two fins formed using nFET materials, a contact connecting two fins formed using pFET materials, and a common gate contact connecting nFET and pFET gates on the four fins). In an embodiment, a single contact 95 is formed. Contacts 95 can be formed using conventional contact materials and processes for VFET fabrication.

As depicted in FIG. 16, a portion of dielectric material 93 is selectively removed over top S/D 92N of the two left most fins 12 and over a portion of ILD 91 between the two top S/D 92N and a contact material is deposited to form a contact of contacts 95 connecting two left most fins of nFET transistors forming connected nFET VFET devices. Similarly, a portion of dielectric material 93 is selectively removed over the two top S/D 92P of the two right most fins 12 and over a portion of ILD 91 between top S/D 92P and a contact material is deposited to form a contact of contacts 95 connecting two right most fins of pFET transistors forming connected pFET VFET devices. In various embodiments, two different materials are used for the top S/D material and in the bottom S/D material in an inverter with two different transistor types. For example, top S/D 92N and S/D layer 11 is composed of an nFET source/drain material, such as Si:P, although not limited to this material and top S/D 92P and S/D layer 11B is composed of a pFET source/drain material, such as SiGe:B (boron doped silicon), although not limited to this material.

Additionally, portions of dielectric material 93, ILD 91 and dielectric material 90 are removed above STI 44 along with a portion of gate materials 78a and 78b, and portions of gate dielectric 77 in the area above of the removed dummy fin (e.g., depicted in the center of semiconductor structure 160) and a contact of contacts 95 that connects gate materials 78a and 78b. The contact of contacts 95 connecting gate material 78b of the leftmost or last nFET VFET transistor to gate material 78a of the rightmost or last pFET VFET transistor. A common gate contact, as depicted in FIG. 16, connects gate materials of adjacent VFET transistors of different transistor types that are separated by isolation structures (e.g., STI 44 and an isolation structure created in place of the dummy fin). One of contacts 95, creating a common gate contact, can be formed after removal of dielectric material 93, ILD 91, and dielectric material 90. Similarly, dielectric material 93, ILD 91, and bottom spacer 66 can be removed from the leftmost side of semiconductor structure 160 and the rightmost side of semiconductor structure 160 outside of gate material 78a and 78b, respectively, in order to form contacts 95 connecting S/D bottom source/drain to the top surface of semiconductor structure 160. A number of bottom source/drain contacts or a number of device type contacts (e.g., nFET and pFET) is not limited to two contacts but can be more or less contacts.

As depicted in FIG. 16, semiconductor structure 160 creates an inverter with the two fins on the left side of semiconductor structure 160 forming nFET transistor devices and the two fins on the right side of semiconductor structure 160 forming pFET transistor devices. One of contacts 95 connecting the two fins 12 of nFET transistors forming VFET devices (e.g., nFET transistor devices formed by leftmost fins 12) in the inverter while contacts 95 connecting two fins 12 of pFET transistor forming VFET devices (e.g., nFET transistor devices formed by right most fins 12). The number of the fins contacts 95 connect in each transistor type is not limited to the number of fins depicted in FIG, 16 or to the number of fins for each transistor type depicted. In some embodiments, the number of fins of fins 12 and the number of each the various device types or transistor types, such as nFETs and pFETs, is limited by space available on a chip or a wafer.

In various embodiments, the centermost contact of contacts 95 is a common gate contact connecting gate material 78a and gate material 78b (e.g., gate materials for each of the nFET transistor devices and each of the pFET transistor devices). For example, a common gate contact of contacts 95 can connect a gate workfunction metal that is a pFET compatible material, such as a boron doped SiGe based material used for gate material 78b and a gate workfunction metal that is a nFET compatible material, such as a phosphorous doped silicon material used for gate material 78a. As depicted in FIG. 16, the two leftmost fins of the nFET transistor device and the two right most fins of the pFET device with depicted isolation structures and the plurality of contacts 95 form an inverter. For example, the inverter is a static CMOS inverter with a common gate contact (e.g., contact 95 over isolation structures) that straps or connects the two gates (e.g., formed by gate materials 78a and 78b) from the top. While FIG. 16 depicts an inverter formed using four fins of the plurality of fins 12, embodiments of the present invention are not limited to four fins in the depicted embodiment but, in other embodiments, use a different number of fins, a different number of fins for each type of transistor device (e.g., nFETs or pFETs), and are not limited to inverters. For example, the method of creating a uniform sacrificial material height in the plurality of recesses by using dummy or isolation fins provides a more uniform gate formation with a more uniform gate length (e.g., uniform sacrificial material height in recesses between fins results in uniform gate height) and can be applied in any suitable array of fins forming one or more vertical field effect devices (VFET devices).

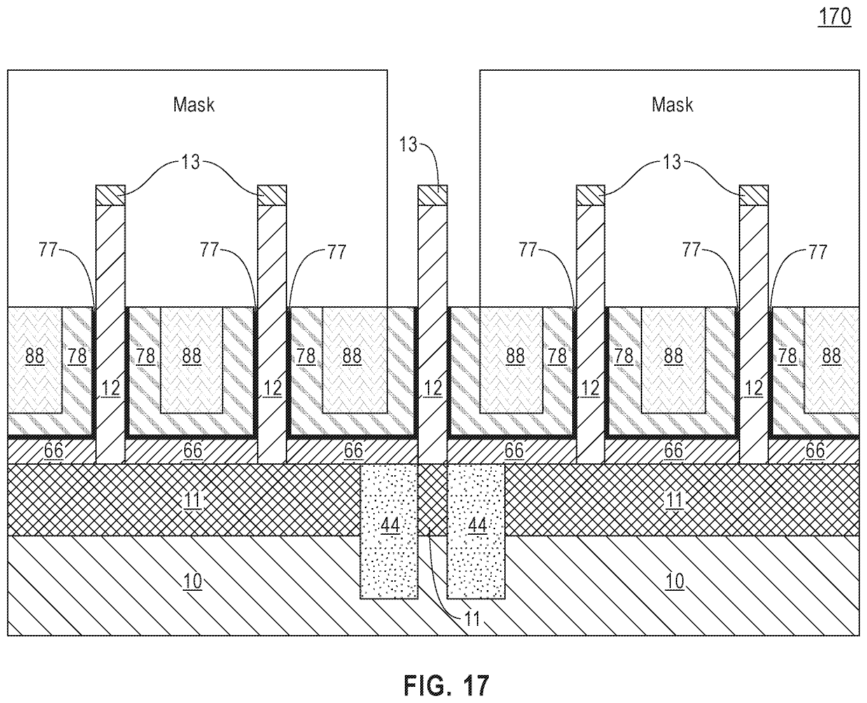

FIG. 17 depicts a cross-sectional view of semiconductor structure 170 in a second embodiment of the present invention after fabrication steps removing the portion of sacrificial material 88 uniformly between each of the plurality of fins 12 to deposit and a patterned etch mask over the semiconductor structure 170, in accordance with an embodiment of the present invention. As depicted, FIG. 17 includes substrate 10, S/D layer 11, STI 44, bottom spacer 66, fins 12, HM 13, gate dielectric 77, gate material 78, sacrificial material 88, and the patterned etch mask. After forming semiconductor structure 1000 as depicted in FIG. 10, the patterned etch mask is deposited over the top surface of semiconductor structure 170, leaving a dummy fin of the plurality of fins 12 exposed and portions of gate dielectric 77 and gate material 78 adjacent to or on the sidewall of the dummy fin of fins 12 exposed. While depicted as a single dummy fin, as previously discussed, one or more dummy fins of fins 12 in various locations within a fin array can be exposed in order to provide desired fin arrangement (e.g., for various transistor devices in the array of fins or array of VFETs upon completion).

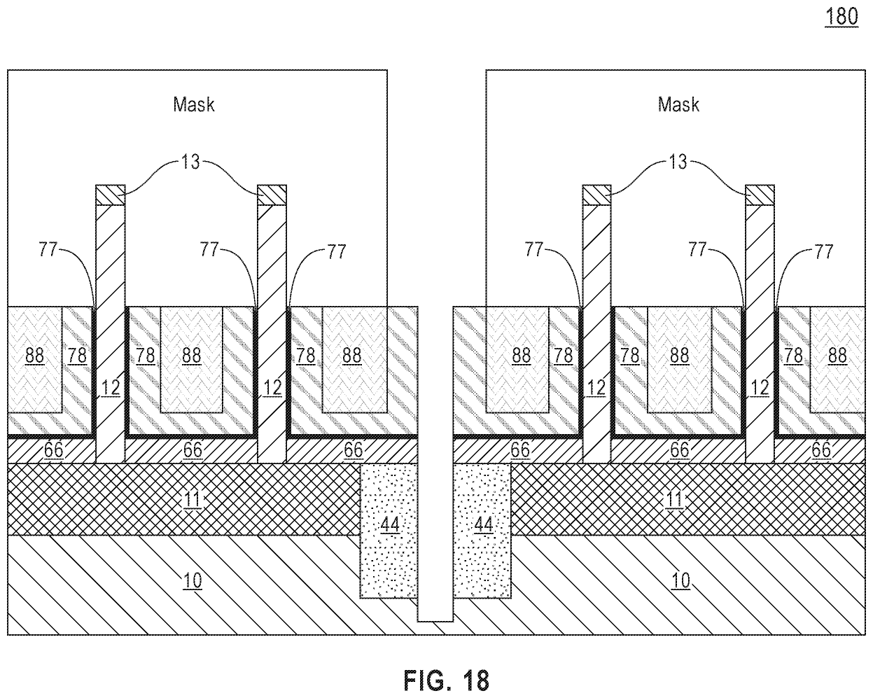

FIG. 18 depicts a cross-sectional view of semiconductor structure 180 in a second embodiment of the present invention after fabrication steps removing exposed fin 12 with HM 13, a portion of gate dielectric 77 on exposed fin 12 (e.g., a dummy fin), a portion of S/D layer 11 under the exposed fin 12, and a portion of substrate 10 under the exposed fin 12, in accordance with an embodiment of the present invention. Using one or more etch processes, exposed fin 12 (e.g., dummy fin) with HM 13, portions of gate dielectric 77 on the exposed fin 12, and the portions of S/D layer 11 and substrate 10 under the exposed fin 12 to create another trench or another isolation trench as previously discussed in detail with reference to FIGS. 11-13. In an embodiment, gate dielectric 77 on the exposed fin 12 is not removed. As previously stated with respect to the first embodiment (e.g., FIGS. 11 and 16 discussion), any number exposed fins 12 or any number of dummy fins can be removed for isolation trench formation can be present in various embodiments.

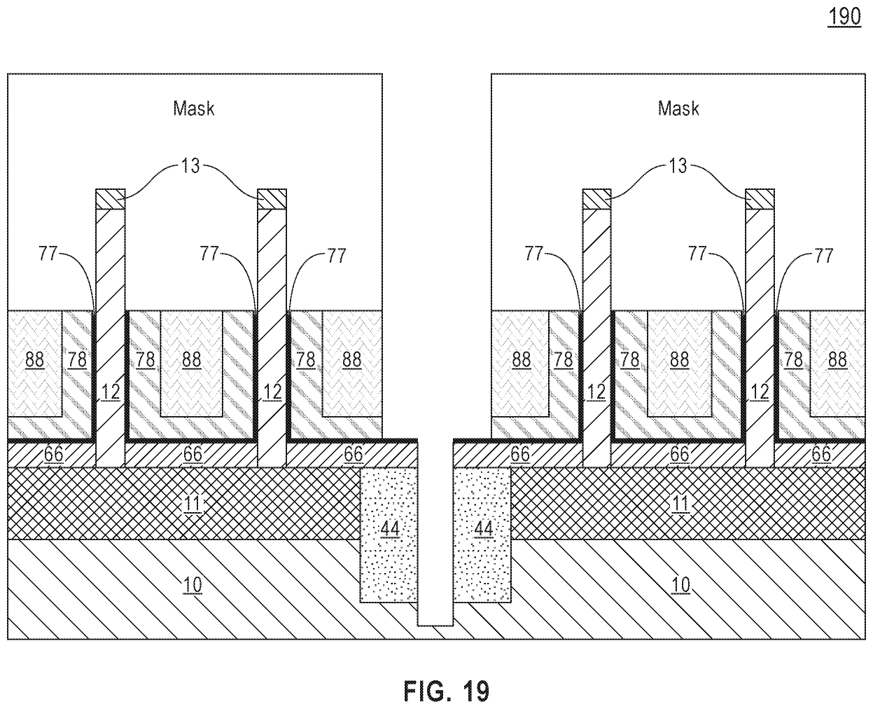

FIG. 19 depicts a cross-sectional view of semiconductor structure 190 in a second embodiment of the present invention after fabrication steps removing exposed portions of gate material 78 adjacent to removed fin 12, in accordance with an embodiment of the present invention. Using one or more etch processes, exposed portions of gate material 78 are removed. In one embodiment, gate dielectric 77 under the removed gate material 78 is also removed. In an embodiment, gate dielectric 77 surrounding removed fin 12 and under gate material 78 adjacent to removed fin 12 is removed. In another embodiment, gate dielectric 78 over bottom spacer 66 adjacent to removed dummy fin is not removed.

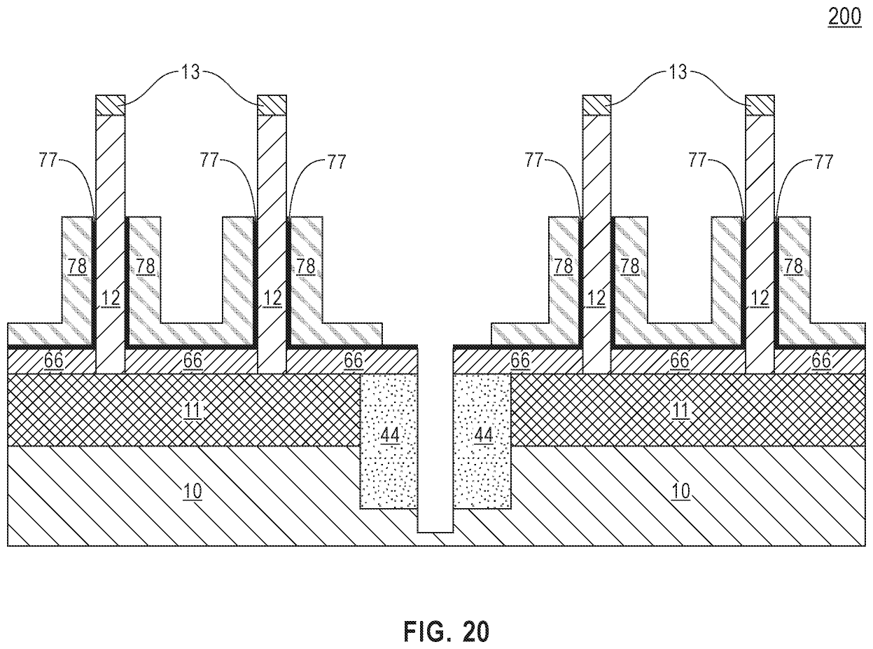

FIG. 20 depicts a cross-sectional view of semiconductor structure 200 in a second embodiment of the present invention after fabrication steps removing the patterned etch mask and remaining sacrificial material 88, in accordance with an embodiment of the present invention. The etch mask is stripped and sacrificial material 88 is removed. Sacrificial material 88 can be etched using one or more etch processes or removed using commercial products associated with sacrificial material 88 removal.

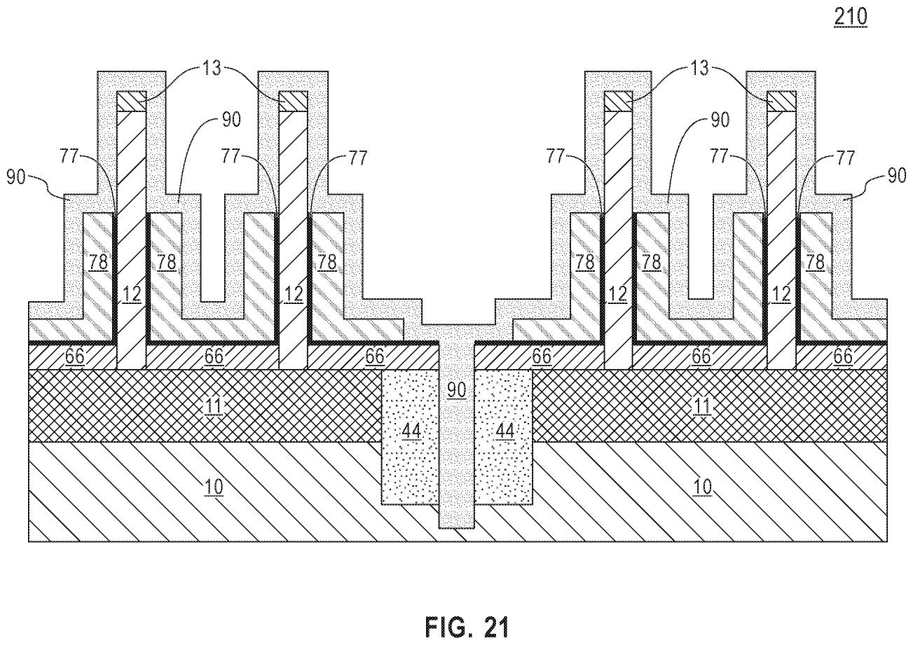

FIG. 21 depicts a cross-sectional view of semiconductor structure 210 in a second embodiment of the present invention after fabrication steps depositing a layer of dielectric material 90 on the exposed surfaces of fins 12, HM 13, gate material 78, gate dielectric 77 and in the recess created by the removed exposed fin 12, in accordance with an embodiment of the present invention. Using processes and materials as previously discussed with respect to FIG. 13, a layer of dielectric material 90 is conformally coated in the top exposed surfaces of fins 12, gate material 78 and gate dielectric 77 as well as inside the trench formed by the removal of exposed fin 12 (e.g., dummy fin) and portions of S/D layer 11 and substrate 10 under the removed fin 12. As depicted, dielectric material 90 completely fills the recess or trench created by the removal of the isolation or dummy fin and the portions of S/D layer 11 and substrate 10 under the removed fin. Various thickness of dielectric material 90 can be deposited in order to fill the recess or trench formed by the removal of the isolation fin and associated portions of the source/drain layer and the semiconductor substrate. In one embodiment, the thickness of dielectric material 90 is greater than one half the width of the recess created after fin 12 removal. For example, 6 nanometers of dielectric material 90 composed of SiN is deposited. In various embodiments, a location of an isolation trench filled with dielectric material that was created by the removal of a dummy fin (e.g., exposed fin 12) and portions of S/D layer 11 and substrate 10 under the dummy fin is on a spacing to an adjacent fin that is consistent with the spacing of the array of fins to which the adjacent fin is a part of (e.g., as previously discussed in detail with reference to FIG. 13).

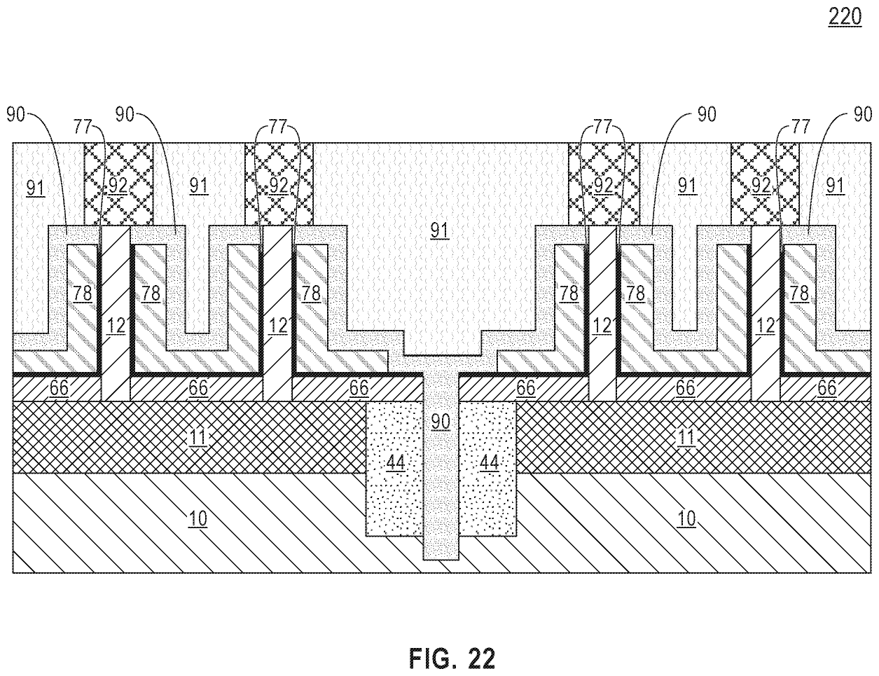

FIG. 22 depicts a cross-sectional view of semiconductor structure 220 in a second embodiment of the present invention after fabrication steps depositing a layer of ILD 91 and form top S/D 92 on top of each of the plurality of fins 12, in accordance with an embodiment of the present invention. Using various known patterning techniques and deposition processes including epitaxy, ILD 91 is deposited and top source/drains (e.g., top S/D 92) are formed. As previously discussed with reference to the first embodiment in FIGS. 1 and 16, while depicted as a single gate material 78, gate material 78 can be more than one material depending the electrical requirements of the transistor device (e.g., a nFET or pFET) and similarly, the number of fins 12 connected by contacts can be varied depending on the electrical requirements of the VFET device. In various embodiments, an interlevel dielectric layer, such as ILD 91 is deposited and one or more contacts are formed. In some embodiments, one or more types of devices, such as an nFET and pFET, are formed using respective materials for gates, source/drains, and contacts associated with nFETs and pFETs. As depicted in FIG. 22, gate dielectric 77 and gate material 78 are removed from the isolation region or isolation structures formed in the steps of FIGS. 2-4 and FIGS. 11-13 as illustrated and discussed with reference to the first embodiment. Semiconductor structure 220 provides a different structure in the isolation regions adjacent to and associated with a dummy fin (e.g., dummy fin removal and trench fill). As previously discussed with reference to FIG. 16, a number of fins of fins 12 and more than one material for gate material 78, gate dielectric 77, and source/drain materials for S/D layer 11 and top S/D 92 can be used. Semiconductor structure 220 is not limited to single materials for gates, source/drains, or the number fins and device type depicted in FIG. 22.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed:

1. An array of vertical field effect transistors comprising:
at least one isolation structure;
a first dielectric material covering a gate material of the plurality of vertical field effect transistors and filling a first isolation structure of the at least one isolation structures, wherein the gate material is a same height as each fin of the array of vertical field effect transistors, and wherein the first isolation structure is located a same distance to an adjacent fin in a vertical field effect transistor of the array of vertical field effect transistors as a distance between each fin in each vertical field effect transistor in the array of vertical field effect transistors; and
a second dielectric material of a second isolation structure surrounding the first isolation structure, wherein the second isolation structure does not extend under the adjacent fin.

2. The array of vertical field effect transistors of claim 1, wherein each vertical field effect transistor of the array of vertical field effect transistors consists of a top source/drain over a fin, a bottom source/drain under the fin, a gate dielectric surrounding the fin and on a portion of a bottom spacer, the gate material over the gate dielectric, the gate material covered by a dielectric material and, wherein the gate material and the gate dielectric extend a uniform height from the bottom spacer on each fin of each of the vertical field effect transistors.

3. The array of vertical field effect transistors of claim 1, wherein each fin in each of the array of vertical field effect transistors is spaced a same distance apart.

4. The array of vertical field effect transistors of claim 3, wherein the first isolation structure is located the same distance apart from an adjacent fin that is a fin in a vertical field effect transistor at an outer edge of the array of vertical field effect transistors.

5. The array of vertical field effect transistors of claim 1, wherein one or more of the first isolation structures are located a same distance apart from a fin adjacent to each of the one or more of the first isolation structures as each fin in the array of vertical field effect transistors is to each other fin in the array of vertical field effect transistors.

6. The array of vertical field effect transistors of claim 2, wherein the gate dielectric and the gate material covered by the first dielectric material are over a bottom spacer and around sidewalls of each fin in the array of vertical field effect transistors, wherein the gate material is a same height as the gate material on each fin in the array of vertical field effect transistors.

7. The array of vertical field effect transistors of claim 3, wherein the first isolation structure is located the same distance apart from an adjacent fin in a portion of the array with one or more fins forming pFET vertical field effect transistors.

8. An array of vertical field effect transistors comprising:
a plurality of vertical field effect transistors and at least one isolation structure, wherein a first portion of the array of vertical field effect transistors is composed of more than one nFET vertical field effect transistor and a second portion of the array of vertical field effect transistors is composed of more than one pFET vertical field effect transistor;
a first dielectric material covering the array of vertical field effect transistors and filling a first isolation structure of the at least one isolation structures, wherein the first isolation structure is located in a distance to an adjacent fin that is a distance consistent with a spacing of each fin in the array of vertical field effect transistors;
a first contact connects each of the nFET vertical field effect transistors in the first portion of the array;
a second contact connects each of the pFET vertical field effect transistors in the second portion of the array;
a third contact connects a nFET gate from a last nFET vertical field effect transistor in the first portion of the array of vertical field effect transistors adjacent to a pFET gate of an adjacent pFET vertical field effect transistor in the second portion of the array of vertical field effect transistors; and
a fourth contact and a fifth contact each provide a connection to one of: a nFET bottom source/drain or to a pFET bottom source/drain.

9. The array of vertical field effect transistors of claim 8, wherein each vertical field effect transistor of the array of vertical field effect transistors consists of a top source/drain over a fin, a bottom source/drain, a gate dielectric surrounding the fin and on a portion of a bottom spacer, a gate material over the gate dielectric covered by a dielectric material and wherein, the array of vertical effect transistors forms an inverter.

10. The array of vertical field effect transistors of claim 8, wherein the array of field effect transistors forms an inverter.

11.-20. (canceled)

21. The array of vertical field effect transistors of claim 8, wherein the at least one isolation structure further comprises:
a second dielectric material surrounding the at least one isolation structure, wherein a second isolation structure does not extend under the adjacent fin in the array of vertical field effect transistors;
an interlevel dielectric material covers the first dielectric material and surrounds each top source/drain in each vertical field effect transistor of the array of vertical field effect transistors; and
a third dielectric material over the interlevel dielectric material surrounding each contact of a plurality of contacts to each vertical field effect transistor in the array of vertical field effect transistors.

22. The array of vertical field effect transistors of claim 8, wherein the plurality of vertical field effect transistors and at least one isolation structure further comprises:
each vertical field effect transistor of the array of vertical field effect transistors consists of a top source/drain over a fin, a bottom source/drain under the fin, a gate dielectric surrounding the fin and on a portion of a bottom spacer, the gate material over the gate dielectric, the gate material covered by a dielectric material and, wherein the gate material and the gate dielectric extend a same height from the bottom spacer as each fin of each of the vertical field effect transistors.

23. The array of vertical field effect transistors of claim 8, wherein each fin in each of the array of vertical field effect transistors is spaced a same distance apart.

24. The array of vertical field effect transistors of claim 23, wherein the at least one isolation structure is located the same distance apart from an adjacent fin that is a fin in a vertical field effect transistor at an outer edge of the array of vertical field effect transistors.

25. The array of vertical field effect transistors of claim 8, wherein the at least one isolation structure are located a same distance apart from a fin adjacent to each of the at least one isolation structure as each fin in the array of vertical field effect transistors is to each other fin in the array of vertical field effect transistors.

26. The array of vertical field effect transistors of claim 22, wherein the gate dielectric and the gate material covered by the first dielectric material are over a bottom spacer and around sidewalls of each fin in the array of vertical field effect transistors, wherein the gate material is a same height as the gate material on each fin in the array of vertical field effect transistors.

27. The array of vertical field effect transistors of claim 23, wherein the at least one isolation structure is located the same distance apart from an adjacent fin in a portion of the array with one or more fins forming pFET vertical field effect transistors as the distance from the adjacent fin in the portion of the array with one or more nFET vertical field effect transistors.
